(19) United States
(12) Patent Application Publication
(10) Pub. No.: US 2026/0123293 A1
(43) Pub. Date: Apr. 30, 2026

(54) SEMICONDUCTOR DEVICE AND METHOD OF FORMING THEREOF

(71) Applicant: Taiwan Semiconductor Manufacturing Company, Ltd., Hsinchu (TW)

(72) Inventors: Ching-Pei HSIEH, Kaohsiung City (TW); I-Ching CHEN, Taichung City (TW); Yung-Hsieh LIN, Tainan City (TW); Ding-I LIU, Hsinchu City (TW)

(73) Assignee: Taiwan Semiconductor Manufacturing Company, Ltd., Hsinchu (TW)

(21) Appl. No.: 18/933,538

(22) Filed: Oct. 31, 2024

(51) Int. Cl. H10N 70/00; H10B 63/00

(52) U.S. Cl. CPC H10N 70/063; H10B 63/30; H10N 70/021; H10N 70/066; H10N 70/068; H10N 70/841; H10N 70/8833

(57) ABSTRACT

A method of forming a semiconductor device includes a number of operations. A first metal line is formed in a first inter-metal dielectric (IMD) layer. A second IMD layer is formed over the first IMD layer. A resistive random access memory (RRAM) cell is formed and embedded in the second IMD layer, wherein the RRAM cell includes a bottom electrode, a top electrode and a resistance switchable layer between the top electrode and the bottom electrode, and the first metal line is in contact with the bottom electrode of the RRAM cell. A third IMD layer is formed over the second IMD layer. A second metal line is formed in the third IMD layer, wherein the second metal line is in contact with the top electrode of the RRAM cell.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

In integrated circuit (IC) devices, resistive random access memory (RRAM) is an emerging technology for next generation non-volatile memory devices. RRAM is a memory structure including an array of RRAM cells each of which stores a bit of data using resistance values. Particularly, RRAM cell includes a resistive material layer, the resistance of which can be adjusted to represent logic “0” or logic “1.”

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross sectional view of a resistive random access memory (RRAM) device with a TEVA and BEVA in accordance with some embodiments of the present disclosure.

FIG. 2 illustrates a cross sectional view of a RRAM cell of the RRAM device of FIG. 1 in accordance with some embodiments of the present disclosure.

FIGS. 3 through 13 illustrate cross-sectional views of formation of a RRAM cell in accordance with some embodiments of the present disclosure.

FIG. 14 illustrates a cross sectional view of a RRAM cell of the RRAM device in accordance with some embodiments of the present disclosure.

FIG. 15 illustrates a cross sectional view of a RRAM cell of the RRAM device in accordance with some embodiments of the present disclosure.

FIG. 16 illustrates a cross sectional view of a RRAM cell of the RRAM device in accordance with some embodiments of the present disclosure.

FIG. 17 illustrates a top view of a RRAM device in accordance with some embodiments of the present disclosure.

FIGS. 18A through 18C illustrate top views of RRAM cells in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Integrated memory refers to memory technologies that are built directly onto a microchip or integrated circuit, rather than being separate or “discrete” components. One such technology is Resistive Random Access Memory (RRAM), also known as ReRAM (Resistive RAM) or memristor-based memory. RRAM is a non-volatile memory technology that has benefits including high density, low power, and fast access.

RRAM operates on a principle of resistive switching. RRAM uses materials that can change their resistance state between a high-resistance (OFF) state and a low-resistance (ON) state in response to an applied voltage. These materials typically have a thin insulating layer sandwiched between two electrodes. By applying voltage pulses of selected magnitudes, the resistance of the insulating layer can be switched between its different states. RRAM is a non-volatile memory technology, which means it retains stored data even when power is turned off. RRAM devices use relatively low power to switch their resistance states, which can contribute to energy-efficient operation in integrated circuits. RRAM devices have the potential to offer fast read and write access times compared to some other non-volatile memory technologies, making them suitable for applications requiring quick data retrieval. RRAM that can be integrated in advanced semiconductor manufacturing processes is beneficial to integration into modern microchips without major modifications to an existing fabrication process. A planar memory device may include two separate planar devices, including a single transistor (IT) and a single resistor (1R) that are typically positioned in two separate metal layers as electrodes. Hence, device density increases become difficult.

Various embodiments of the present disclosure relates to resistive random access memory (RRAM) device having a RRAM cell connected between an overlying metal line and an underlying metal line. In one or more embodiments of the present disclosure, the RRAM cell includes a bottom electrode, a top electrode and a resistance switchable layer between the bottom electrode and the top electrode, wherein the bottom electrode can be served as a bottom electrode via (BEVA) structure directly connected to the underlying metal line, and the top electrode can be served as a top electrode via (TEVA) structure directly connected to the overlying metal line. In some embodiments, both of the top electrode and the bottom electrode of the RRAM cell can be defined in an inter-metal dielectric (IMD) layer in which the RRAM cell is formed within. Dimensions of the RRAM cell can thus be reduced. In some embodiments, insulation films may be formed between the top electrode and the bottom electrode of the RRAM cell, and an etch stop layer (ESL) can limit contact areas of the resistance switchable layer and the bottom electrode. In some embodiments, an ESL may be formed over the bottom electrode and surround the top electrode, and the ESL can isolate the bottom electrode and the resistance switchable layer from the overlying metal line and limit contact areas of the top electrode and the overlying metal line.

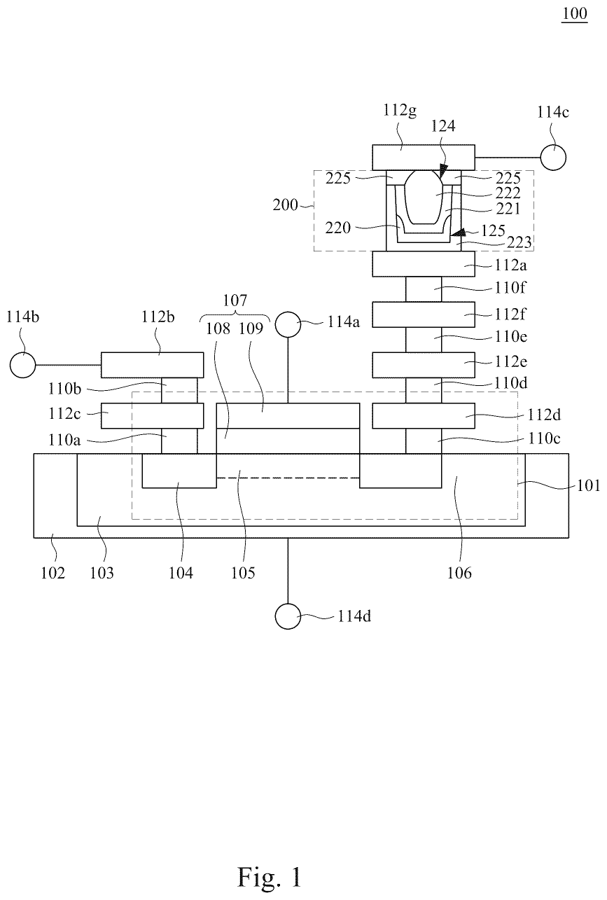

Reference is made to FIG. 1. FIG. 1 illustrates a cross sectional view of a resistive random access memory (RRAM) device 100 in accordance with some embodiments of the present disclosure. As illustrated in FIG. 1, the RRAM device 100 includes a RRAM cell 200. In some embodiments, a plurality of such RRAM devices form a memory array configured to store data.

In one or more embodiments, a selection transistor is associated with each RRAM device. The selection transistor is configured to suppress sneak-path leakage (i.e., prevent current intended for a particular memory cell from passing through an adjacent memory cell) while providing enough driving current for memory cell operation. In one or more embodiments, the RRAM device 100 includes a planar MOSFET selection transistor 101 and a RRAM cell 200. The RRAM cell 200 is electrically connected to the transistor 101.

As illustrated in FIG. 1, the RRAM device 100 includes a substrate 102. The substrate 102 may be a semiconductor substrate, such as a bulk semiconductor, or the like, which may be doped (e.g., with a p-type or an n-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; other compound semiconductors including gallium, zinc, indium and/or oxygen; or combinations thereof. Other substrates, such as single-layer, multi-layered, or gradient substrates may be used.

The selection transistor 101 is formed over the substrate 102. In one or more embodiments of the present disclosure, the transistor 101 includes a semiconductor well 103 formed in the substrate 102. For example, the semiconductor well 103 may be doped with impurities to form either n-type (with donor impurities like phosphorus or arsenic) semiconductor for NMOS or p-type (with acceptor impurities like boron) semiconductor for PMOS.

The transistor 101 may further include source/drain regions 104 and 106 and a channel region 105 in the semiconductor well 103. In FIG. 1, the source/drain regions 104 and 106 may be heavily doped regions in the semiconductor well 103 of the substrate 102. The channel region 105 between the source/drain regions 104 and 106 is lightly doped with the opposite conductive type of impurity compared to the source/drain regions 104 and 106. For example, an NMOS may have a p-type channel (e.g., with boron), and a PMOS may have an n-type channel (e.g., with phosphorus). In some embodiments, the source/drains 104 and 106 are doped with carbon.

As illustrated in FIG. 1, the transistor 101 may include a gate structure 107 over the substrate 102. The gate structure 107 may include a gate dielectric layer 108 extending laterally over the surface of the channel region 105 of the semiconductor well 103 and a gate electrode 109 over the gate dielectric layer 108. The gate electrode 109 is separated from the source/drain regions 104 and 106 by the gate dielectric layer 108. In some embodiments, the gate dielectric layer 108 may be or include silicon dioxide (SiO₂) or a high-k dielectric, such as hafnium oxide (HfO₂) that is beneficial to reduce leakage and improve performance. In some embodiments, the gate electrode 109 may include suitable conductive material such as metal material or poly silicon.

The RRAM device 100 may be selectively accessed using word lines and bit lines for reading, writing and erasing operations. In one or more embodiments of the present disclosure, one or more metal lines including metal lines 112c, 112d, 112e, 112f and metal vias include metal vias 110a, 110b, 110c, 110d, 110e, 110f that helps in connecting the RRAM device 100 with the external circuitry may be present between the source/drain region 106 and the metal line 112a, and the source/drain region 104 and the metal line 112b. In some embodiments, the metal lines 112a, 112b, 112c, 112d, 112e, 112f may include copper (Cu) or other suitable conductive material.

In FIG. 1, the source/drain region 106 is connected to a data storage element or RRAM cell 200 by way of a first metal line 112a. The source/drain region 104 is connected by way of a second metal line 112b. The gate electrode 109 of the gate structure 107 is connected to a word line 114a, the source/drain region 104 is connected to a select line 114b through the second metal line 112b and the RRAM cell 200 is further connected to a bit line 114c within an upper metallization layer by way of an additional metal line 112g. In some embodiments, the semiconductor substrate 102 may be connected to a substrate line 114d.

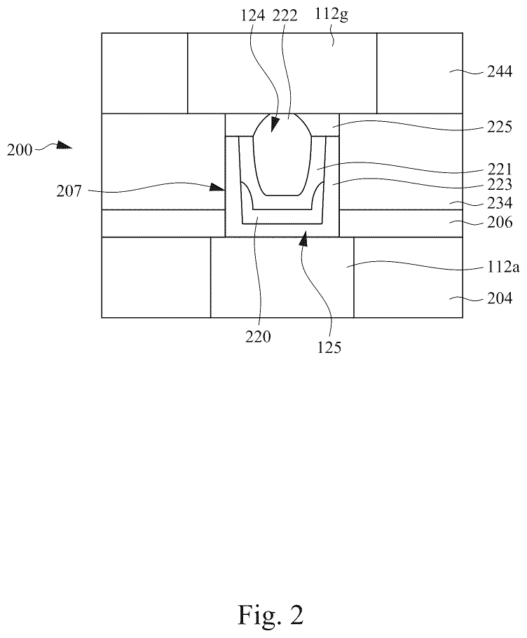

In one or more embodiments of the present disclosure, the RRAM cell 200 is directly between the metal lines 112a and 112g. Reference is made to FIGS. 1 and 2 to illustrate a structure of the RRAM cell 200 of the RRAM device 100 in accordance with some embodiments of the present disclosure. FIG. 2 illustrates a cross sectional view of the RRAM cell 200 of the RRAM device 100 of FIG. 1 in accordance with some embodiments of the present disclosure. As illustrated in FIG. 2, the metal line 112a is formed in an inter-metal dielectric (IMD) layer 204. The metal line 112g is formed in an IMD layer 244. The RRAM cell 200 is formed in a dielectric layer including an etch stop layer (ESL) 206 over the IMD layer 204 and an IMD layer 234 over the ESL 206 and under the IMD layer 244. In some embodiments, the ESL 206 includes silicon carbide (SiC). In some embodiments, the IMD layers 204, 234 and 244 may be an extremely low-k dielectric layer such as porous silicon dioxide, fluorinated silica glass, polyimides, polynorbornenes, benzocyclobutene, or PTFE.

In one or more embodiments of the present disclosure, the RRAM cell 200 of the RRAM device 100 includes a bottom electrode 223. The bottom electrode 223 is in contact with the underlying metal line 112a. In one or more embodiments of the present disclosure, the bottom electrode 223 can be served as a bottom electrode via (BEVA) structure to connect the RRAM cell 200 to the underlying metal line 112a.

As shown in FIGS. 1 and 2, an insulation film 220 is over the bottom electrode 223. In some embodiments, an entirely of inner horizontal surface and lower portions of the inner sidewalls of the bottom electrode 223 is covered by the insulation film 220. The resistance switchable layer 221 is over the insulation film 220. The resistance switchable layer 221 is over the bottom electrode 223 and covers upper portions of the inner sidewalls of the bottom electrode 223. The top electrode 222 is filled with a recess of the resistance switchable layer 221 and is spaced apart from the insulation film 220.

In FIG. 2, the bottom electrode 223 and the resistance switchable layer 221 are recessed from a top surface of the IMD layer 234. Topmost surfaces of the bottom electrode 223 and the resistance switchable layer 221 are lower than a topmost surface of the top electrode 222. An etch stop layer (ESL) 225 is filled with a recess between the top electrode 222 and the IMD layer 234. The ESL 225 is around the top electrode 222 and over the bottom electrode 223 and the resistance switchable layer 221. In FIGS. 1 and 2, the topmost surface of the top electrode 222 is level with a top surface of the ESL 225. The bottom electrode 223 and the resistance switchable layer 221 are spaced apart from the overlying metal line 112g by the ESL 225.

In one or more embodiments of the present disclosure, the top electrode 222 and the bottom electrode 223 may include titanium (Ti), tantalum (Ta), titanium nitride (TiN), tantalum nitride (TaN) or suitable conductive material. In some embodiments, the top electrode 222 and the bottom electrode 223 may have different conductive material, an etch selectivity of the top electrode 222 and the bottom electrode 223 can be provided, and the top electrode 222 and the bottom electrode 223 can be etched at the same time so that the topmost surface of the etched bottom electrode 223 is lower than the topmost surface of the top electrode 222.

In some embodiments, the insulation film 220 includes silicon (Si), silicon nitride (SiN), silicon carbide (SiC), silicon oxynitride (SiON) or any suitable dielectric material formed over the bottom electrode 223.

In some embodiment, the resistance switchable layer 221 may include a thin insulating layer such as a variable resistive dielectric layer between the top electrode 222 and the bottom electrode 223. The variable resistive dielectric layer is normally insulating, but a sufficient voltage applied to the variable resistive dielectric material will form one or more conductive pathways in the variable resistive dielectric. Through the appropriate application of various voltages (e.g. a set voltage and reset voltage), the conductive pathways may be modified to form a high resistance state or a low resistance state. The variable resistive dielectric layer is one that can be induced to undergo a reversible phase change between a high resistance state and a low resistance state. In some embodiments, the change is between an amorphous state and a metallic state. The phase change can be accompanied by or associated with a change in molecular structure. For example, an amorphous metal oxide may lose oxygen as it undergoes a phase change to a metallic state. The oxygen may be stored in a portion of variable resistive dielectric layer that remains in the amorphous state or in an adjacent layer. Variable resistive dielectric layer is described as dielectric with reference the high resistance state. In the low resistance state, variable resistive dielectric layer may be a conductive material. For example, in the low resistance state, the variable resistive dielectric layer may include a high-k dielectric with one or more conductive filaments that extend from the bottom electrode to the top electrode, wherein these filaments effectively render the variable resistive dielectric layer conductive. In some embodiments, these filaments are broken in the low resistance state, such that the variable resistive dielectric layer is a high-k dielectric that fully separates the top electrode 222 and bottom electrode 223 while in the high resistance state. In some embodiments, variable resistive dielectric layer is a transitional metal oxide. Examples of materials that can be suitable for variable resistive dielectric layer include NiO_{X}, Ta_{y}O_{X}, TiO_{X}, HfO_{X}, WO_{X}, ZrO_{X}, Al_{y}O_{X}, and SrTiO_{X}.

In some embodiments, the resistance switchable layer 221 may include a capping layer. A capping layer may provide an oxygen storage function that facilitates phase changes within resistance switchable layer 221. In some embodiments, the capping layer is a metal or a metal oxide that is relatively low in oxygen concentration. Examples of metals that can be suitable for a capping layer include Ti, Hf, Pt and Al. Examples of metal oxides that can be suitable for capping layer include TiO_{X}, HfO_{X}, ZrO_{X}, GeO_{X}, CeO_{X}. A capping layer can have any suitable thickness.

In some embodiments, the ESL 225 includes silicon nitride (SiN), silicon carbide (SiC), silicon oxynitride (SiON) or any suitable dielectric material over the bottom electrode 223 and the resistance switchable layer 221 and around the top electrode 222.

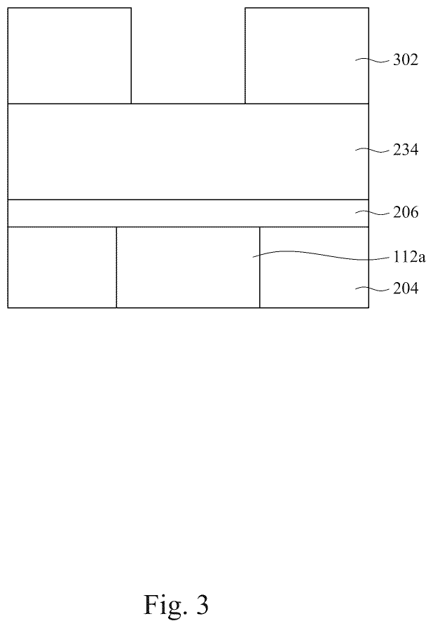

Reference is made to FIGS. 3 through 13. FIGS. 3 through 13 illustrate cross-sectional views of formation of a RRAM cell in accordance with some embodiments of the present disclosure.

As illustrated in FIG. 3, the metal line 112a is formed within the IMD layer 204. An ESL 206 is formed over the IMD layer 204 and the metal line 112a. In some embodiments, the ESL 206 may include SiC. An IMD layer 234 is formed over the ESL 206. In some embodiments, the IMD layer 234 may include extreme low-k dielectric material. The ESL 206 and the IMD layer 234 may be formed using suitable deposition process.

A patterned mask 302 with an opening is subsequently formed over the IMD layer 234 for patterning the IMD layer 234 and the ESL 206. The mask 302 may be formed using photolithography. The mask formed using lithography may be a photoresist mask but may also be a hard mask such as a nitride hard mask that is patterned using a photoresist mask.

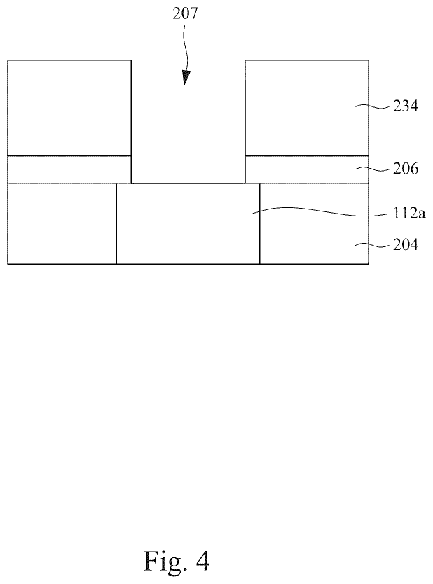

As illustrated in FIG. 4, after the mask 302 has been used to form an opening 207 in the IMD layer 234 and the etch stop layer 206 then stripped away. The opening 207 is formed by etching areas of the IMD layer 234 and the ESL 206 that are left exposed by the patterned mask 302. The opening 207 exposes the metal line 112a within the IMD layer 204. In FIG. 4, the metal line 112a is wider than the opening 207.

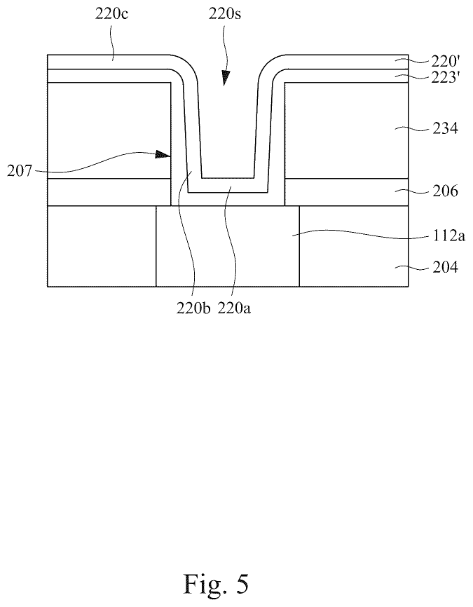

Continuing to FIG. 4, FIG. 5 illustrates that a bottom electrode layer 223′ is conformally formed over exposed top surface of IMD layer 234, inner sidewalls of the opening 207 through the IMD layer 234 and the ESL 206 and the exposed top surface of the metal line 112a. The bottom electrode layer 223′ may include titanium (Ti), tantalum (Ta), titanium nitride (TiN), tantalum nitride (TaN) or suitable conductive material. In some embodiments, the bottom electrode layer 223′ may be formed by a suitable deposition process. In some embodiments, the bottom electrode layer 223′ may be a material that is protected from copper diffusion by a diffusion barrier layer such as a TiN layer.

After the bottom electrode layer 223′ is formed, in one or more embodiments of the present disclosure, an insulation material 220′ is deposited over a recessed region of the bottom electrode layer 223′ and is entirely over the top surface of the bottom electrode layer 223′. In some embodiments, the insulation material 220′ includes silicon nitride (SiN), silicon carbide (SiC), silicon oxynitride (SiON) or any suitable dielectric material deposited over the bottom electrode layer 223′. As illustrated in FIG. 5, after the insulation material 220′ is formed, the opening 207 is not completely filled. The formed insulation material 220′ has a first portion 220a over the inner horizontal surface of the opening 207, second portions 220b over the sidewalls of the opening 207 and third portions 220c extending out of the opening 207 and along the top surface of the bottom electrode layer 223′. In some embodiments, the insulation material 220′ can be interchangeably referred to as a spacer layer.

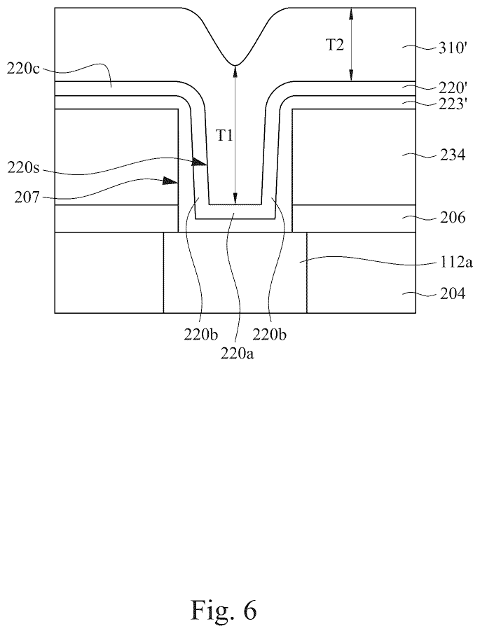

Reference is made to FIG. 6. After the insulation material 220′ is formed, a bottom anti-reflective coating (BARC) layer 310′ is formed over the insulation material 220′. Entireties of the first portion 220a, the second portions 220b and the third portions 220c of the insulation material 220′ are covered by the BARC layer 310′. In FIG. 6, the formed BARC layer 310′ may be filled with the recess 220s of the insulation material 220′. In some embodiments, the BARC layer 310′ may include photoresist material formed over the insulation material 220′ by a spin-coating technique. In some embodiments, as shown in FIG. 6, the BARC layer 310′ has a recess aligned with the recess 220s of the insulation material 220′. In some embodiments, the BARC layer 310′ formed by the spin-coating technique may have a flat top surface. In some embodiments, the BARC layer 310′ formed by the spin-coating technique may have non-uniform thicknesses. For example, as shown in FIG. 6, the BARC layer 310′ may have a first portion extending in the recess 220s with a first thickness T1 and second portions out of the recess with a second thickness T2, and the thickness T1 is greater than thickness T2.

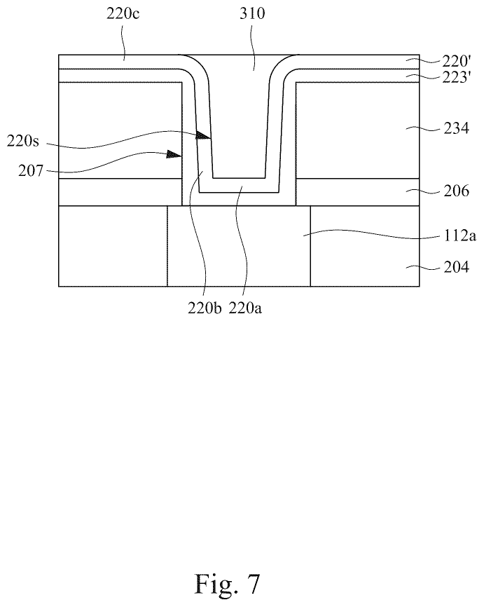

Reference is made to FIG. 7. In some embodiments, after the BARC layer 310′ is formed, the BARC layer 310′ can be uniformly exposed to a light such as UV light or EUV light. The exposure to light cause a chemical change that allows some of the BARC layer 310′ to be removed by developers. In one or more embodiments of the present disclosure, since the BARC layer 310′ has non-uniform thicknesses, the BARC layer 310′ may have the first portion 310 remaining in the recess 220s of the insulation material 220′ after the second portions of the BARC layer 310′ out of the recess 220s are removed. The first portion 310 of the BARC layer 310′ remaining in the recess 220s may be served as a mask layer 310 over the first portion 220a and the second portions 220b of the insulation material 220′. The third portions 220c of the insulation material 220′ are exposed after the mask layer 310 is formed.

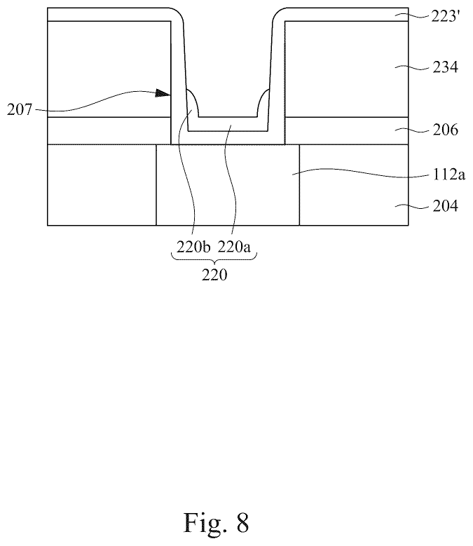

After the mask layer 310 is formed, the insulation material 220′ is etched based on the mask layer 310. Reference is made to FIGS. 7 and 8 to illustrate etching the insulation material 220′ based on the mask layer 310. The third portions 220c of the insulation material 220′ are removed. The second portions 220b on the upper inner sidewalls of the bottom electrode layer 223′ are removed. As illustrated in FIG. 8, after the insulation material 220′ is etched, the second portions 220b on the lower inner sidewalls of the bottom electrode layer 223′ and the first portion 220a remain and can be served as an insulation film 220 over the bottom electrode layer 223′. After the insulation material 220′ is etched to form insulation film 220, the mask layer 310 is removed as illustrated in FIG. 8. In some embodiments, the insulation film 220 has an U-shaped profile along the bottom electrode layers 223′. In some embodiments, the insulation film 220 can be regarded as a spacer limiting a contact area of the bottom electrode layer 223′. As shown in FIG. 8, the upper inner sidewalls of the bottom electrode layers 223′ are exposed.

In some embodiments, the insulation material 220′ is etched by, for example, a dry etching process using plasma or a wet etching to form the insulation film 220. As illustrated in FIG. 8, during etching the insulation material 220′, the bottom electrode layer 223′ overlaps the underlying IMD layer 234. The IMD layer 234 may be protected by the bottom electrode layer 223′ during etching the insulation material 220′ so that plasma damage to the IMD layer 234 can be reduced.

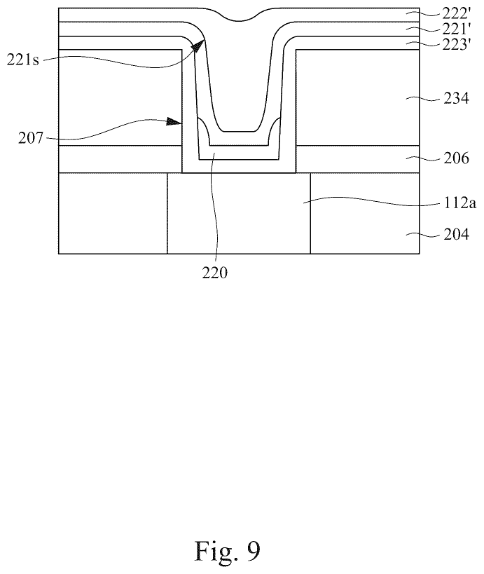

Reference is made to FIG. 9, after the insulation film 220 is formed, a resistance switchable layer 221′ is formed along the insulation film 220 and the exposed surface of the bottom electrode layer 223′. In some embodiments, the resistance switchable layer 221′ is formed over the upper inner sidewalls of the bottom electrode layer 223′ exposed from the insulation film 220. In some embodiments, the contact area of the resistance switchable layer 221′ and the bottom electrode layer 223′ can be increased by etching the insulation material 220′ during formation of the insulation film 220, and less portions of the inner sidewalls of the bottom electrode layer 223′ is covered by the insulation film 220. In some embodiments, the resistance switchable layer 221′ may be a resistive dielectric layer deposited over the bottom electrode layer 223′ and the insulation film 220. In some embodiments, variable resistive dielectric layer is a transitional metal oxide. Examples of materials that can be suitable for variable resistive dielectric layer include NiO_{X}, Ta_{y}O_{X}, TiO_{X}, HfO_{X}, WO_{X}, ZrO_{X}, Al_{y}O_{X}, and SrTiO_{X}. Since the resistance switchable layer 221 is formed along the bottom electrode layer 223′, the insulation film 220, the resistance switchable layer 221 has a recess 221s extending into the opening 207 of the bottom electrode layer 223′. In some embodiments, the resistance switchable layer 221′ may include capping layer formed over the variable resistive dielectric layer. In some embodiments, the capping layer of the resistance switchable layer 221′ is a metal or a metal oxide that is relatively low in oxygen concentration. Examples of metals that can be suitable for the capping layer of the resistance switchable layer 221′ may include Ti, Hf, Pt and Al.

In FIG. 9, a top electrode layer 222′ is formed over the resistance switchable layer 221′. The top electrode layer 222′ may include titanium (Ti), tantalum (Ta), titanium nitride (TiN), tantalum nitride (TaN) or suitable conductive material. In some embodiments, the top electrode layer 222′ may be formed by a suitable deposition process. In FIG. 9, the top electrode layer 222′ is filled with a recess 221s of the resistance switchable layer. The top electrode layer 222′ has the bottommost top surface higher that the topmost surfaces of the bottom electrode layer 223′ and the resistance switchable layer 221′.

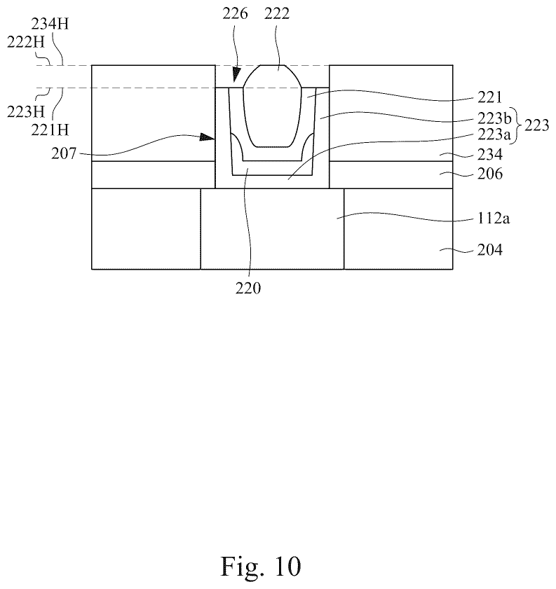

Reference is made to FIG. 10. FIG. 10 illustrates etching the bottom electrode layer 223′, the resistance switchable layer 221′ and the top electrode layer 222′ in accordance with some embodiments. After performing the etching process to the bottom electrode layer 223′, the resistance switchable layer 221′ and the top electrode layer 222′, a bottom electrode 223, a resistance switchable layer 221 and a top electrode 222 are formed. In one or more embodiments, the top electrode layer 222′ and the bottom electrode layer 223′ have different material and an etch rate of the top electrode layer 222′ is less than an etch rate of the bottom electrode layer 223′ in an etch process to the bottom electrode layer 223′, the resistance switchable layer 221′ and the top electrode layer 222′, so that topmost surfaces of the bottom electrode 223 and the resistance switchable layer 221 is lower than a topmost surface of the top electrode 222.

As shown in FIG. 10, the bottom electrode 223 has a first portion 223a extending laterally along a top surface of the first metal line 112a and second portions 223b extending along sidewalls of the opening 207 in the IMD layer 234 and the ESL 206. The insulation film 220 covers least a partial region of the first portion 223a of the bottom electrode 223. In FIG. 10, the insulation film 220 is over the inner horizontal surface of the first portion 223a of the bottom electrode 223 and over the inner sidewalls of the second portions 223b of the bottom electrode 223. The resistance switchable layer 221 is over the inner sidewalls of the second portions 223b of the bottom electrode 223 exposed from the insulation film 220.

In some embodiments, prior to etching the bottom electrode layer 223′, the resistance switchable layer 221′ and the top electrode layer 222′ to form the bottom electrode 223, the resistance switchable layer 221 and the bottom electrode 223, a planarization process such as a chemical-mechanical planarization (CMP) can performed to the bottom electrode layer 223′, the resistance switchable layer 221′ and the top electrode layer 222′ higher than the top surface of the IMD layer 234. The CMP process is carried out to remove excess materials of the bottom electrode layer 223′, the resistance switchable layer 221′ and the top electrode layer 222′ outside the opening 207, while leaving a portion of the bottom electrode layer 223′ in the opening 207 to serve as a bottom electrode 223, leaving a portion of the resistance switchable layer 221′ in the opening 207 to serve as a resistance switchable layer 221, and leaving a portion of the top electrode layer 222′ to serve as a top electrode 222. Topmost surfaces of the bottom electrode layer 223′, the resistance switchable layer 221′, the top electrode layer 222′ and the IMD layer 234 may be level with each other after performing the planarization process. The etching process having an etch selectivity of the bottom electrode layer 223′ and the top electrode layer 222′ is then performed to recess the bottom electrode layer 223′ and the resistance switchable layer 221′.

As illustrated in FIG. 10, topmost surfaces of the bottom electrode 223 and the resistance switchable layer 221 is lower than a topmost surface of the top electrode 222. A recess 226 is formed and around an upper portion of the top electrode 222. In some embodiment, an elevation 223H of the topmost surface of the bottom electrode 223 is level with an elevation 221H of the resistance switchable layer 221. In some embodiments, the elevation 223H of the topmost surface of the bottom electrode 223 is different from the elevation 221H of the resistance switchable layer 221. In some embodiment, an elevation 222H of the topmost surface of the top electrode 222 is level with an elevation 234H of the IMD layer 234. In some embodiments, the elevation 222H of the topmost surface of the top electrode 222 is different from the elevation 234H of the IMD layer 234. For example, in some embodiments, the elevation 222H of the topmost surface of the top electrode 222 is higher than the elevation 234H of the IMD layer 234.

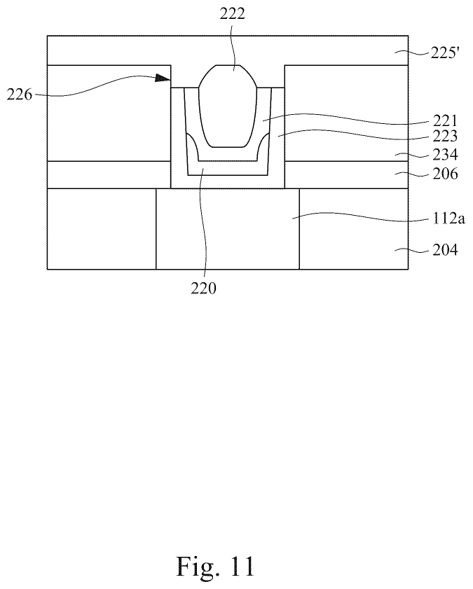

Reference is made to FIG. 11. FIG. 11 illustrates forming an etch stop layer (ESL) 225′ filled with the recess 226 around the upper portion of the top electrode 222 in accordance with some embodiments. In one or more embodiments of the present disclosure, the ESL 225′ may include silicon (Si), silicon nitride (SiN), silicon carbide (SiC), silicon oxynitride (SiON) or any suitable dielectric material formed over the top electrode 222 and the IMD layer 234. In some embodiments, the ESL 225′ can be formed by any suitable deposition process.

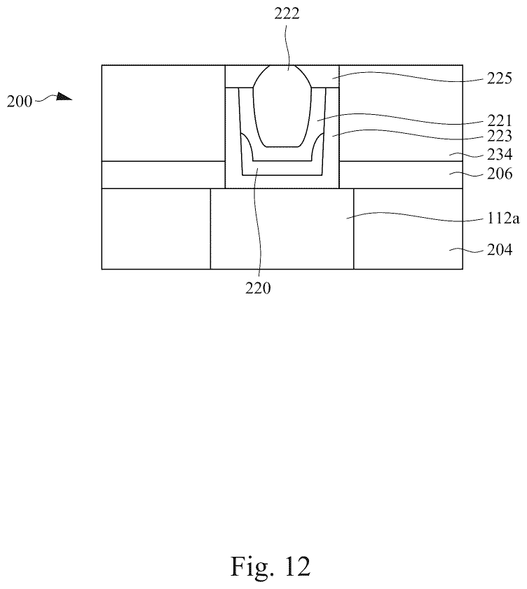

FIG. 12 illustrates performing a planarization process such as a chemical-mechanical planarization (CMP) to the ESL 225′ in accordance with some embodiments. The CMP process is carried out to remove excess materials of the ESL 225′ outside the recess 226, while leaving a portion of the ESL 225′ in the recess 226 to serve as a ESL 225 around the upper portion of the top electrode 222. The top electrode 222 is exposed after the ESL 225 is formed. In FIG. 12, the top surface of the ESL 225 is level with the top surface of the top electrode 222 is level with the top surfaces of the top electrode 222 and the IMD layer 234. In some embodiments, the elevation 222H (see FIG. 10) of the top electrode 222 may be higher than the elevation 234H of the IMD layer 234, and the planarization process to the ESL 225′ may be performed to the top electrode 222.

After the planarization process is performed, the RRAM cell 200 is defined within the IMD layer 234 and the ESL 206. The bottom electrode 223 and the resistance switchable layer 221 have U-shaped profiles. The insulation film 220 is between the bottom electrode 223 and the resistance switchable layer 221. The top electrode 222 is over the insulation film 220. The ESL 225 is over the bottom electrode 223 and the insulation film 220 and around the upper portion of the top electrode 222.

In one or more embodiments of the present disclosure, a cell size of the RRAM cell 200 is the same as a size of the opening 207 and can be determined by the patterned mask 302 as illustrated in FIG. 3. The cell size of the RRAM cell 200 can thus be reduced based on the design of the patterned mask 302. In some embodiments, as illustrated in FIG. 12, a width of the RRAM cell 200 is less than a width of the metal line 112a.

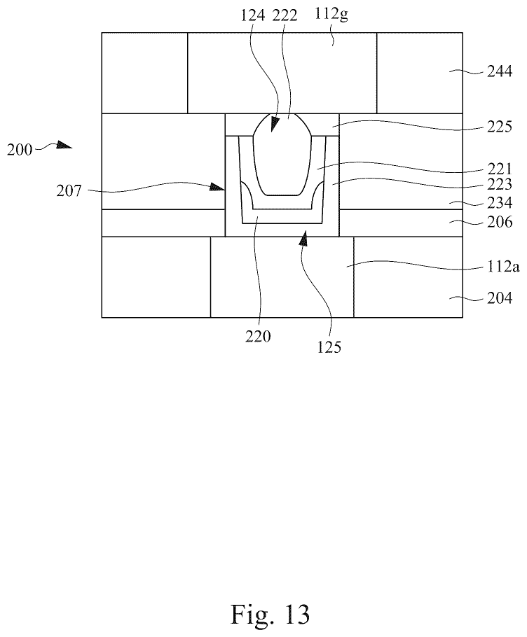

Reference is made to FIG. 13. FIG. 13 illustrates forming the metal line 112g over the RRAM cell 200 in accordance with some embodiments. In FIG. 13, after the planarization process is performed to form the RRAM cell 200, an IMD layer 244 is formed over the IMD layer 234, the ESL 225 and the top electrode 222. The metal line 112g is formed in the IMD layer 244. In some embodiments, formation of the metal line 112g may include etching an opening in the IMD layer 244 to the RRAM cell 200 and forming conductive material in the opening, wherein etching the opening in the IMD layer 244 stops at the ESL 225 of the RRAM cell 200. As illustrated in FIG. 12, a width of the RRAM cell 200 is less than a width of the metal line 112g.

As illustrated in FIG. 13, the underlying metal line 112a is in contact with the bottom electrode 223 of the RRAM cell 200, and the bottom electrode 223 can thus be served as a bottom electrode via (BEVA) structure 125 forming connecting the RRAM cell 200 to the underlying metal line 112a. The upper portion of the top electrode 222 of the RRAM cell 200 is in contact with the overlying metal line 112g, and the upper portion of the top electrode 222 wrapped by the ESL 225 can thus be served as a top electrode via (TEVA) structure 124 connecting the RRAM cell 200 to the overlying metal line 112g. In one or more embodiments of the present disclosure, both of the TEVA structure 124 and the BEVA structure 125 are defined in the dielectric layer including the IMD layer 234 and the ESL 206, and it is able to shrink the cell size of the RRAM cell 200.

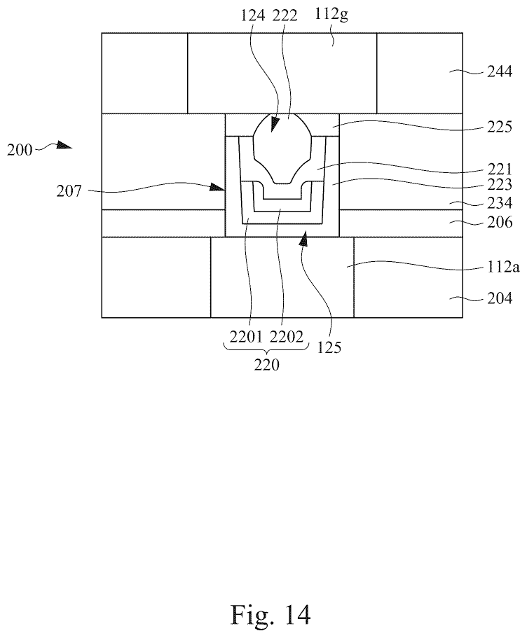

In some embodiments, the insulation film 220 may include numbers of insulation layers. FIG. 14 illustrates a cross sectional view of a RRAM cell 200 of the RRAM device 100 in accordance with some embodiments of the present disclosure. As illustrated in FIGS. 13 and 14, the RRAM cell 200 in FIG. 14 may be substantially the same as the RRAM cell 200 in FIG. 13, except that the insulation film 220 in FIG. 14 includes a first insulation layer 2201 over the bottom electrode 223 and a second insulation layer 2202 over the first insulation layer 2201. In some embodiments, formation of the first insulation layer 2201 and the second insulation layer 2202 may include sequentially depositing the first insulation layer 2201 and the second insulation layer 2202 over the bottom electrode layer 223′ (see FIG. 5) and etching the first insulation layer 2201 and the second insulation layer 2202 so that the topmost surfaces of the first insulation layer 2201 and the second insulation layer 2202 are lower than the topmost surfaces of the bottom electrode layer 223′. For example, the first insulation layer 2201 and the second insulation layer 2202 can be etched based on the mask layer 310 as illustrated in FIG. 7. In FIG. 14, both of the first insulation layer 2201 and the second insulation layer 2202 of the insulation film 220 have U-shaped profiles extending along the U-shaped bottom electrode 223. The inner horizontal surface and lower portions of the inner sidewalls of the bottom electrode 223 is covered by the insulation film 220.

In some embodiments, the contact area of the resistance switchable layer 221 and the bottom electrode 223 can be determined based on the insulation film 220. Reference is made to FIGS. 14 through 16 to illustrate the resistance switchable layer 221 and the bottom electrode 223 having different contact areas according to the different insulation films 220. In one or more embodiments of the present disclosure, by controlling the etching of the insulation layer 220, the contact area of the resistance switchable layer 221 and the bottom electrode 223 can be determined.

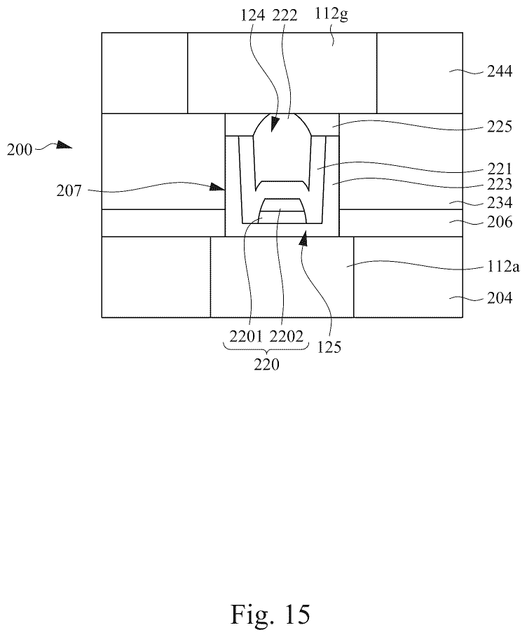

FIG. 15 illustrates a cross-sectional view of a RRAM cell 200 of the RRAM device 100 in accordance with some embodiments of the present disclosure. As illustrated in FIGS. 14 and 15, a difference between the RRAM cell 200 in FIG. 14 and the RRAM cell 200 in FIG. 15 may include that the inner sidewalls and portions of the inner horizontal surface of the bottom electrode 223 are not covered by the insulation film 220 including the first insulation layer 2201 and the second insulation layer 2202. The insulation film 220 remains on a center region of the inner horizontal surface of the bottom electrode 223. In FIG. 15, entireties of the inner sidewalls of the bottom electrode 223 are in contact with the resistance switchable layer 221. The bottom electrode 223 further includes the portions of the inner horizontal surface in contact with the resistance switchable layer 221 adjacent the inner sidewalls of the bottom electrode 223.

In some embodiments, the first insulation layer 2201 and the second insulation layer 2202 may include silicon (Si), silicon nitride (SiN), silicon carbide (SiC), silicon oxynitride (SiON) or any suitable dielectric material. In some embodiments, the first insulation layer 2201 and the second insulation layer 2202 are made of different dielectric materials. Therefore, the first insulation layer 2201 and the second insulation layer 2202 can have different etch selectivity, thereby facilitating forming the insulation film 220 with target geometry.

In some embodiments, formation of the first insulation layer 2201 and the second insulation layer 2202 as illustrated in FIG. 15 may include sequentially depositing the first insulation layer 2201 and the second insulation layer 2202 over the bottom electrode layer 223′ (see FIG. 5) and etching the first insulation layer 2201 and the second insulation layer 2202 so that the inner horizontal surface of the bottom electrode layer 223′ is exposed. In the cross-sectional view as illustrated in FIG. 15, the first insulation layer 2201 and the second insulation layer 2202 have trapezoid profiles spaced apart from the inner sidewalls of the bottom electrode 223. The resistance switchable layer 221 is then formed along the exposed surfaces of the bottom electrode layer 223′ and the insulation film 220. In FIG. 15, the formed resistance switchable layer 221 has portions extending between sidewalls of the insulation film 220 of the first insulation layer 2201 and the second insulation layer 2202 and the inner sidewalls of the bottom electrode 223, and the resistance switchable layer 221 has a W-shaped profile around the insulation film 220. The top electrode 222 is filled the recess 221s of the resistance switchable layer 221 and has fangs extend towards gaps between the insulation film 220 and the inner sidewalls of the bottom electrode 223.

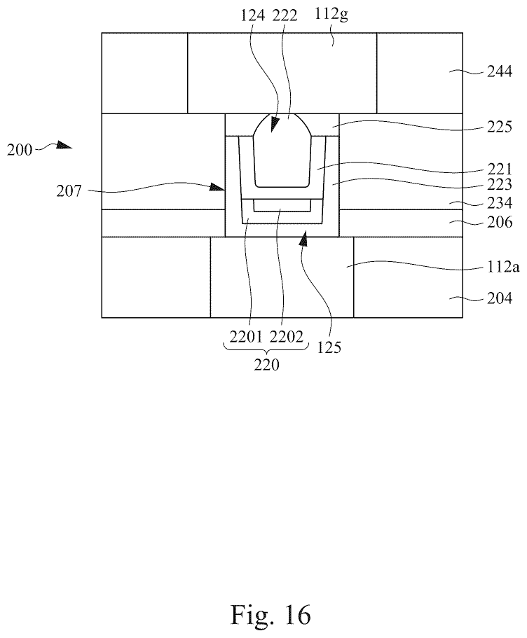

FIG. 16 illustrates a cross sectional view of a RRAM cell 200 of the RRAM device 100 in accordance with some embodiments of the present disclosure. As illustrated in FIGS. 14 and 16, a difference between the RRAM cell 200 in FIG. 14 and the RRAM cell 200 in FIG. 16 may include the insulation film 220 in FIG. 16 has a flat top surface. In FIG. 16, the first insulation layer 2201 has an U-shaped profile, and the second insulation layer 2202 filled with a recess of the U-shaped first insulation layer 2201. The resistance switchable layer 221 and the top electrode 222 are sequentially formed over the insulation film 220 and thus have bottom surfaces parallel to the flat top surface of the insulation film 220.

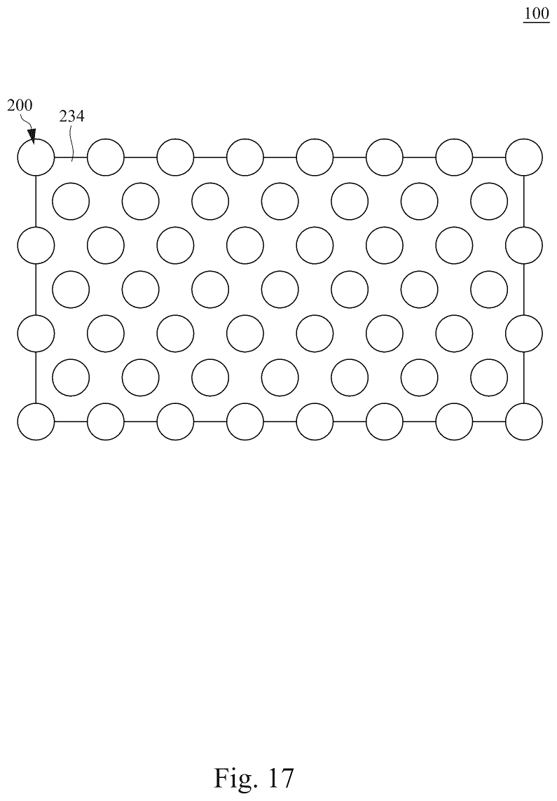

As illustrated in FIGS. 13 through 16, in one or more embodiments of the present disclosure, the RRAM cell 200, the BEVA structure 125 and the TEVA structure 124 of the RRAM cell 200 may be formed in the opening 207 in the dielectric layer (e.g., the IMD layer 234 and the ESL 206) in which the RRAM cell is formed within. The cell size of the formed RRAM cell 200 may be controlled based on the opening 207 through the dielectric layer of the IMD layer 234 and the ESL 206. Therefore, since the formed RRAM cells 200 are embedded in the dielectric layer, the cell sizes of the formed RRAM cells 200 are determined when the openings 207 in which the RRAM cells 200 are formed within are defined and RRAM cell density can be increased. FIG. 17 illustrates a top view of a RRAM device 100 in accordance with some embodiments of the present disclosure FIG. 17 illustrates a top view of a RRAM device 100 in accordance with some embodiments of the present disclosure. As illustrated in FIG. 17, each of the RRAM cells 200 in the IMD layer 234 may be in the middle of immediately-adjacent four of the RRAM cells 200 so that the RRAM cells 200 may be arranged in a dense manner according to the arrangement to the openings 207, wherein each of the openings 207 may be in the middle of immediately-adjacent four of the openings 207.

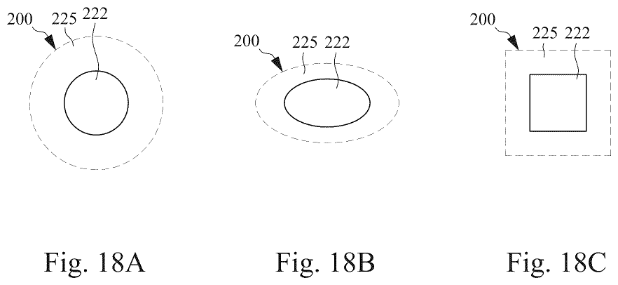

In one or more embodiments of the present disclosure, the cell profile of the formed RRAM cell 200 may be controlled based on the opening through dielectric layer of the IMD layer 234 and the ESL 206. The ESL 225 in the opening through the IMD layer 234 and the ESL 206 may limit the contact area of the top electrode 222 and the overlying metal line (e.g., the metal line 112g as illustrated in FIG. 1). In some embodiments, the ESL 225 is around the upper portion of the top electrode 222 and the upper portion of the top electrode 222 surrounded by the ESL 225 can be served as the TEVA structure of the RRAM cell 200. FIGS. 18A through 18C illustrate top views of RRAM cells 200 in accordance with some embodiments of the present disclosure. FIG. 18A illustrates that the RRAM cell 200 has a circle-profile from a top view. FIG. 18B illustrates that the RRAM cell 200 has an oval-profile from a top view. FIG. 18C illustrates that the RRAM cell 200 has a rectangle profile from a top view.

According to one or more embodiments of the present disclosure, a method of forming a semiconductor device includes a number of operations. A first metal line is formed in a first inter-metal dielectric (IMD) layer. A second IMD layer is formed over the first IMD layer. A resistive random access memory (RRAM) cell is formed and embedded in the second IMD layer, wherein the RRAM cell includes a bottom electrode, a top electrode and a resistance switchable layer between the top electrode and the bottom electrode, and the first metal line is in contact with the bottom electrode of the RRAM cell. A third IMD layer is formed over the second IMD layer. A second metal line is formed in the third IMD layer, wherein the second metal line is in contact with the top electrode of the RRAM cell. In one or more embodiments of the present disclosure, forming the RRAM cell further includes forming an insulation material over the bottom electrode and removing a first portion of the insulation material on inner sidewalls of the bottom electrode, wherein the resistance switchable layer is formed on the inner sidewalls of the bottom electrode. In some embodiments, the method further includes forming a mask layer in a recess of the insulation material, wherein the first portion of the insulation material on the inner sidewalls of the bottom electrode is removed by etching the insulation material when the mask layer is in place. In some embodiments, the method further includes removing a second portion of the insulation material on an inner horizontal surface of the bottom electrode, wherein the resistance switchable layer extends between the inner sidewalls of the bottom electrode and a third portion of the insulation material of the insulation material remains on the inner horizontal surface of the bottom electrode. In one or more embodiments of the present disclosure, forming the RRAM cell further includes etching the bottom electrode and the resistance switchable layer so that topmost surfaces of the bottom electrode and the resistance switchable layer are lower than a topmost surface of the top electrode. In some embodiments, the top electrode is etched when etching the bottom electrode and the resistance switchable layer. In one or more embodiments of the present disclosure, forming the RRAM cell further includes forming an etch stop layer around the top electrode, wherein the bottom electrode and the resistance switchable layer are spaced apart from the second metal line by the etch stop layer.

According to one or more embodiments of the present disclosure, a method of forming a semiconductor device includes a number of operations. A bottom electrode is formed in a first inter-metal dielectric (IMD) layer. An insulation film is formed over a recessed region in the bottom electrode. A resistance switchable layer is formed over the insulation film and in contact with inner sidewalls of the recessed region in the bottom electrode. A top electrode is formed over the resistance switchable layer. The bottom electrode and the resistance switchable layer is etched to form a recess around the top electrode. An etch stop layer is formed and fills up the recess around the top electrode. In one or more embodiments of the present disclosure, the top electrode is etched during etching the bottom electrode and the resistance switchable layer. In one or more embodiments of the present disclosure, the method further includes performing a planarization process on the etch stop layer until the top electrode is exposed. In one or more embodiments of the present disclosure, the method further includes forming a second IMD layer over the first IMD layer and forming a metal line in the second IMD layer and in contact with the top electrode. In some embodiments, the method further includes etching an opening in the second IMD layer, wherein etching the opening stops at the etch stop layer, and the metal line is formed in the opening in the second IMD layer. In one or more embodiments of the present disclosure, the method further includes forming a second IMD layer under the first IMD layer and forming a metal line in the second IMD layer and in contact with the bottom electrode.

According to one or more embodiments of the present disclosure, a semiconductor device includes a first inter-metal dielectric (IMD) layer, a first metal line in the first IMD layer, a second IMD layer, a second metal line in the second IMD layer, a third IMD layer between the first and second IMD layer and a resistive random access memory (RRAM) cell embedded in the third IMD layer. The RRAM cell includes a bottom electrode, an insulation film, a resistance switchable layer, a top electrode and a dielectric layer. The bottom electrode has a first portion extending laterally along a top surface of the first metal line and second portions extending along sidewalls of the third IMD layer. The insulation film covers at least a partial region of the first portion of the bottom electrode. The resistance switchable layer is over the insulation film and in contact with inner sidewalls of the second portions of the bottom electrode. The top electrode is over the resistance switchable layer and in contact with the second metal line. The dielectric layer is around the top electrode. The second metal line is spaced apart from the bottom electrode and the resistance switchable layer by the dielectric layer. In one or more embodiments of the present disclosure, topmost surfaces of the second portions of the bottom electrode are lower than a topmost surface of the top electrode. In one or more embodiments of the present disclosure, a topmost surface of the resistance switchable layer is lower than a topmost surface of the top surface. In one or more embodiments of the present disclosure, a material of the bottom electrode is different from a material of the top electrode. In one or more embodiments of the present disclosure, the insulation film comprises a first insulation layer and a second insulation layer over the first insulation layer. In one or more embodiments of the present disclosure, the resistance switchable layer has a portion extending between the insulation film and the inner sidewall of the second portions of the bottom electrode. In one or more embodiments of the present disclosure, the insulation film has an U-shaped profile.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first metal line in a first inter-metal dielectric (IMD) layer;
forming a second IMD layer over the first IMD layer;
forming a resistive random access memory (RRAM) cell embedded in the second IMD layer, wherein the RRAM cell comprises a bottom electrode, a top electrode and a resistance switchable layer between the top electrode and the bottom electrode, and the first metal line is in contact with the bottom electrode of the RRAM cell;
forming a third IMD layer over the second IMD layer; and
forming a second metal line in the third IMD layer, wherein the second metal line is in contact with the top electrode of the RRAM cell.

2. The method of claim 1, wherein forming the RRAM cell further comprises:
forming an insulation material over the bottom electrode; and
removing a first portion of the insulation material on inner sidewalls of the bottom electrode, wherein the resistance switchable layer is formed on the inner sidewalls of the bottom electrode.

3. The method of claim 2, further comprising:
forming a mask layer in a recess of the insulation material, wherein the first portion of the insulation material on the inner sidewalls of the bottom electrode is removed by etching the insulation material when the mask layer is in place.

4. The method of claim 3, further comprising:
removing a second portion of the insulation material on an inner horizontal surface of the bottom electrode, wherein the resistance switchable layer extends between the inner sidewalls of the bottom electrode and a third portion of the insulation material of the insulation material remains on the inner horizontal surface of the bottom electrode.

5. The method of claim 1, wherein forming the RRAM cell further comprises:
etching the bottom electrode and the resistance switchable layer so that topmost surfaces of the bottom electrode and the resistance switchable layer are lower than a topmost surface of the top electrode.

6. The method of claim 5, wherein the top electrode is etched when etching the bottom electrode and the resistance switchable layer.

7. The method of claim 1, wherein forming the RRAM cell further comprises:
forming an etch stop layer around the top electrode, wherein the bottom electrode and the resistance switchable layer are spaced apart from the second metal line by the etch stop layer.

8. A method comprising:
forming a bottom electrode in a first inter-metal dielectric (IMD) layer;
forming an insulation film over a recessed region in the bottom electrode;
forming a resistance switchable layer over the insulation film and in contact with inner sidewalls of the recessed region in the bottom electrode;
forming a top electrode over the resistance switchable layer;
etching the bottom electrode and the resistance switchable layer to form a recess around the top electrode; and
forming an etch stop layer filling up the recess around the top electrode.

9. The method of claim 8, wherein the top electrode is etched during etching the bottom electrode and the resistance switchable layer.

10. The method of claim 8, further comprising:
performing a planarization process on the etch stop layer until the top electrode is exposed.

11. The method of claim 8, further comprising:
forming a second IMD layer over the first IMD layer; and
forming a metal line in the second IMD layer and in contact with the top electrode.

12. The method of claim 11, further comprising:
etching an opening in the second IMD layer, wherein etching the opening stops at the etch stop layer, and the metal line is formed in the opening in the second IMD layer.

13. The method of claim 8, further comprising:
forming a second IMD layer under the first IMD layer; and
forming a metal line in the second IMD layer and in contact with the bottom electrode.

14. A semiconductor device, comprising:
a first inter-metal dielectric (IMD) layer;
a first metal line in the first IMD layer;
a second IMD layer;
a second metal line in the second IMD layer;
a third IMD layer between the first and second IMD layer; and
a resistive random access memory (RRAM) cell embedded in the third IMD layer, comprising:
a bottom electrode having a first portion extending laterally along a top surface of the first metal line and second portions extending along sidewalls of the third IMD layer;
an insulation film covering at least a partial region of the first portion of the bottom electrode;
a resistance switchable layer over the insulation film and in contact with inner sidewalls of the second portions of the bottom electrode;
a top electrode over the resistance switchable layer and in contact with the second metal line; and
a dielectric layer around the top electrode, wherein the second metal line is spaced apart from the bottom electrode and the resistance switchable layer by the dielectric layer.

15. The semiconductor device of claim 14, wherein topmost surfaces of the second portions of the bottom electrode are lower than a topmost surface of the top electrode.

16. The semiconductor device of claim 14, wherein a topmost surface of the resistance switchable layer is lower than a topmost surface of the top surface.

17. The semiconductor device of claim 14, wherein a material of the bottom electrode is different from a material of the top electrode.

18. The semiconductor device of claim 14, wherein the insulation film comprises a first insulation layer and a second insulation layer over the first insulation layer.

19. The semiconductor device of claim 14, wherein the resistance switchable layer has a portion extending between the insulation film and the inner sidewall of the second portions of the bottom electrode.

20. The semiconductor device of claim 14, wherein the insulation film has an U-shaped profile.
